(19) United States
(12) Patent Application Publication
(10) Pub. No.: US 2014/0042410 A1
(43) Pub. Date: Feb. 13, 2014

(54) TOUCH-SENSING STRUCTURE AND TOUCH-SENSITIVE DEVICE

(71) Applicant: Wintek Corporation, Taichung City (TW)

(72) Inventors: Kuo-Hsing CHEN, Hsin Pei-City (TW); Yu-Ting CHEN, Pingzhen City, Taoyuan County (TW); Kuo-Chang SU, Shan Hua Town, Tai Nan County (TW); Chen-Hao SU, Feng Yuan City, Tai Chung County (TW)

(73) Assignee: Wintek Corporation, Taichung City (TW)

(21) Appl. No.: 13/963,890

(22) Filed: Aug. 9, 2013

(30) Foreign Application Priority Data
Aug. 10, 2012 (TW) 101129007

(51) Int. Cl. H01L 51/52

(52) U.S. Cl. CPC H01L 51/5203
USPC 257/40

(57) ABSTRACT

A touch-sensing structure includes a substrate and a conductive layer. The conductive layer spreads over a surface of the substrate and includes a plurality of first electrodes, a plurality of second electrodes, a plurality of first conductive lines, and a plurality of second conductive lines. The surface is divided into a plurality of regions. The second electrodes are divided into multiple second electrode groups, and each second electrode group is formed by at least one of the second electrodes in each of the regions. Each of the first conductive lines is connected to one of the first electrodes, and each of the second conductive lines is connected to one of the second electrodes. The second conductive lines connected to the second electrodes in the same second electrode group are electrically connected with each other.

### BACKGROUND OF THE INVENTION

a. Field of the Invention

The invention relates to a touch-sensing structure and a touch-sensitive device.

b. Description of the Related Art

Nowadays, a touch-sensing electrode structure of a capacitive touch-sensitive device is often fabricated using double-sided ITO or single-sided ITO fabrication processes. On forming conventional double-sided ITO patterns, coating, etching, and photolithography processes are performed on each of a top side and a bottom side of a glass substrate to form X-axis and Y-axis sensing electrodes on the two sides. However, except for being complicated, such fabrication processes may cause low production yields because of the step of flipping over the glass substrate to achieve double-sided patterning. In comparison, on forming conventional single-sided ITO patterns, since X-axis and Y-axis sensing electrodes are formed on the same side of a glass substrate, a bridge wiring structure needs to be formed in a touch screen area. In that case, unstable material characteristics of an organic insulation layer or other factors may cause short-circuit or open-circuit of the X-axis and Y-axis sensing electrodes. Therefore, a single-layer electrode structure is proposed to resolve above problems, where X-axis and Y-axis sensing electrodes are formed in the same layer to simplify fabrication process, increase production yields and reduce fabrication costs. However, as shown in FIG. 10, a single-layer electrode structure 100 may, for example, include nine driver electrodes 102 aligned in a row and forty-five (9*5) sensing electrodes 104 arranged into nine columns corresponding to the nine driver electrodes 102. Each column contains five sensing electrodes 104, and thus forty-five channels are needed to perform touch-sensing operations. In that case, the amount of channels needed for the single-layer electrode structure 100 is very large. Besides, the amount of channels may also increase as the size of the electrode structure 100 increases. Further, since sensing-electrode traces 106 are located in an active display area, the sensing-electrode traces 106 need a broad width to decrease the line impedance. However, this may result in an excessively high proportion of an area of the sensing-electrode traces 106 to an effective touch-sensing area to thereby affect touch-sensing characteristics.

### BRIEF SUMMARY OF THE INVENTION

The invention provides a touch-sensing structure and a touch-sensitive device having reduced channel amount and low line impedance.

According to an embodiment of the invention, a touch-sensing structure includes a substrate and a conductive layer. The conductive layer spreads over a surface of the substrate and includes a plurality of first electrodes, a plurality of second electrodes, a plurality of first conductive lines, and a plurality of second conductive lines. The surface is divided into a plurality of regions. The first electrodes spread over the regions, and each region is provided with at least one of the first electrodes. The second electrodes spread over the regions and not overlapping the first electrodes, and each region is provided with several of the second electrodes. The plurality of second electrodes are divided into multiple second electrode groups, and each second electrode group is formed by at least one of the second electrodes in each of the regions. Each of the first conductive lines is connected to one of the first electrodes, and each of the second conductive lines is connected to one of the second electrodes. The second conductive lines connected to the second electrodes in the same second electrode group are electrically connected with each other.

In one embodiment, the second conductive lines connected to the second electrodes in the same second electrode group are all connected to the same bus line. The first conductive lines and the second conductive lines are made of a transparent conductive material, and the bus line is made of a metallic material. The bus lines may be formed on a substrate or a flexible printed circuit board.

In one embodiment, the substrate has a lengthwise direction and a widthwise direction, and the first electrodes are arranged along the widthwise direction of the substrate. Each of the first electrodes has a longitudinal direction substantially parallel to the lengthwise direction of the substrate. The first electrodes that are placed in two adjacent regions aligned along the lengthwise direction are disposed symmetrically relative to a border line between the two adjacent regions. The second electrodes in the same second electrode group are disposed symmetrically relative to a border line between two adjacent regions aligned along the lengthwise direction.

In one embodiment, the second conductive lines connected to the second electrodes in the same second electrode group all have an equal length measured in an active display area.

In one embodiment, the first electrodes and the second electrodes in each region have an identical layout.

In one embodiment, only one of the first conductive lines is electrically conducted at a time.

In one embodiment, the first conductive lines do not cross the second conductive lines, and lengths of the first conductive lines and the second conductive lines measured in a non-screen area are set to gradually decrease along a direction towards a signal processing unit.

In one embodiment, one of the second electrodes together with a part of the first electrode near the second electrode forms a mutual-capacitive or self-capacitive touch-sensing unit.

According to another embodiment of the invention, a touch-sensing structure includes a substrate, a conductive layer, a trace layer and a decorative layer. The conductive layer spreads over a surface of the substrate and includes a plurality of first electrodes, a plurality of second electrodes, a plurality of first conductive lines, and a plurality of second conductive lines. The surface is divided into a plurality of regions. The first electrodes spread over the regions, and each region is provided with at least one of the first electrodes. The second electrodes spread over the regions and not overlapping the first electrodes, and each region is provided with several of the second electrodes. The second electrodes are divided into multiple second electrode groups, and each second electrode group is formed by at least one of the second electrodes in each of the regions. Each of the first conductive lines is connected to one of the first electrodes, and each of the second conductive lines is connected to one of the second electrodes. The second conductive lines connected to the second electrodes in the same second electrode group are all electrically connected with each other. The trace layer is disposed on the substrate and connected to the first electrodes and the second electrodes. The decorative layer is disposed on a periphery of the substrate.

In one embodiment, the conductive layer is a transparent conductive layer, and the trace layer is formed on at least a part of the transparent conductive layer.

In one embodiment, the conductive layer is a transparent conductive layer, and the transparent conductive layer is formed on the trace layer and covers the trace layer.

In one embodiment, the decorative layer includes at least one of ceramic, diamond-like carbon, colored ink, photo resist and resin.

In one embodiment, the substrate is made of glass or plastic.

In one embodiment, The touch-sensitive device includes a flexible printed circuit board having a plurality of bus lines, and the second conductive lines connected to the second electrodes in the same second electrode group are all connected to the same bus line.

In one embodiment, an IC chip is disposed on the substrate. The second conductive lines connected to the second electrodes in the same second electrode group are all connected with each other in the IC chip, and a single-layer flexible printed circuit board is electrically connected to the IC chip.

According to another embodiment of the invention, a touch-sensitive device includes a substrate, a conductive layer, a trace layer and a cover lens. The conductive layer spreads over a surface of the substrate and includes a plurality of first electrodes, a plurality of second electrodes, a plurality of first conductive lines, and a plurality of second conductive lines. The surface is divided into a plurality of regions. The first electrodes spread over the regions, and each region is provided with at least one of the first electrodes. The second electrodes spread over the regions and not overlapping the first electrodes, and each region is provided with several of the second electrodes. The second electrodes are divided into multiple second electrode groups, and each second electrode group is formed by at least one of the second electrodes in each of the regions. Each of the first conductive lines is connected to one of the first electrodes, and each of the second conductive lines is connected to one of the second electrodes. The second conductive lines connected to the second electrodes in the same second electrode group are all electrically connected with each other. The trace layer is disposed on the substrate, the trace layer includes a plurality of bus lines, and the second conductive lines connected to the second electrodes in the same second electrode group are connected to the same bus line. The cover lens is connected with the conductive layer or the substrate, and the cover lens may have a decorative layer.

According to the above embodiments, the amount of channels needed for a single-layer touch-sensing structure is decreased, the line impedance is reduced, and the production yields are increased.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram illustrating a touch-sensing structure according to an embodiment of the invention.

FIG. 2 shows a schematic diagram illustrating a wiring layout of the touch-sensing structure shown in FIG. 1 outside a touch screen area.

FIG. 3 shows a schematic diagram illustrating a touch-sensing structure according to another embodiment of the invention.

FIG. 4 shows a schematic diagram illustrating a touch-sensitive device according to an embodiment of the invention.

FIG. 5A shows a schematic diagram illustrating a wiring layout of FIG. 4 according to an embodiment of the invention.

FIG. 5B shows a schematic diagram illustrating a wiring layout according to another embodiment of the invention.

FIG. 5C shows a partially enlarged schematic diagram of FIG. 5B.

FIG. 5D shows a schematic diagram illustrating a wiring layout according to another embodiment of the invention.

FIG. 5E shows a schematic diagram illustrating a wiring layout according to another embodiment of the invention.

FIG. 6 shows a schematic diagram illustrating a touch-sensitive device according to another embodiment of the invention.

FIG. 7 shows a schematic diagram illustrating a touch-sensitive device according to another embodiment of the invention.

FIG. 8 shows a schematic diagram illustrating a touch-sensitive device according to another embodiment of the invention.

FIG. 9 shows a schematic diagram of a touch-sensing structure according to another embodiment of the invention.

FIG. 10 shows a schematic diagram of a conventional touch-sensing structure.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

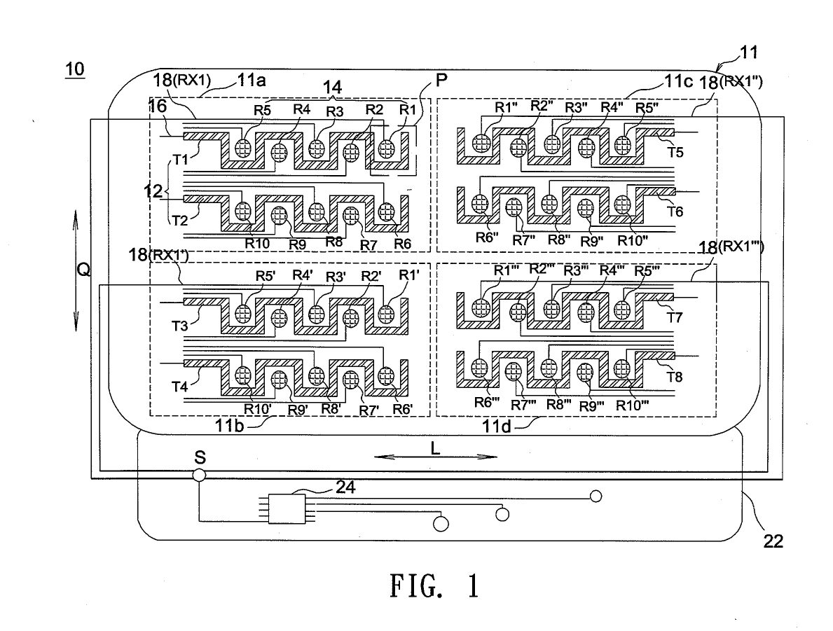

FIG. 1 shows a schematic diagram of a touch-sensing structure 10 according to an embodiment of the invention. In this embodiment, the touch-sensing structure 10 is a single-layer electrode structure. The touch-sensing structure 10 may include a substrate 11 and a conductive layer spreading over a surface of the substrate 11, and, in one embodiment, the conductive layer may be a transparent conductive layer. The conductive layer includes multiple first electrodes 12, second electrodes 14, first conductive lines 16, and second conductive lines 18, and the second electrodes 14 do not overlap the first electrodes 12. In one embodiment, the first electrodes 12 may be referred to as row electrodes, and the second electrodes 14 as column electrodes of the touch-sensing structure 10. In one embodiment, one second electrode 14 together with a part of a first electrode 12 near the second electrode 14 forms one touch-sensing unit P. Thus, the touch-sensing structure 10 shown in FIG. 1 is exemplified to have ten columns and four rows and thus has forty touch-sensing units P. However, it should be noted that the number and shape of the electrodes in rows and columns of the touch-sensing structure 10 are not restricted. Further, the conductive layer may be made of opaque conductive fine wires, such as metal wires. Additionally, the conductive layer may be in the form of a metal mesh.

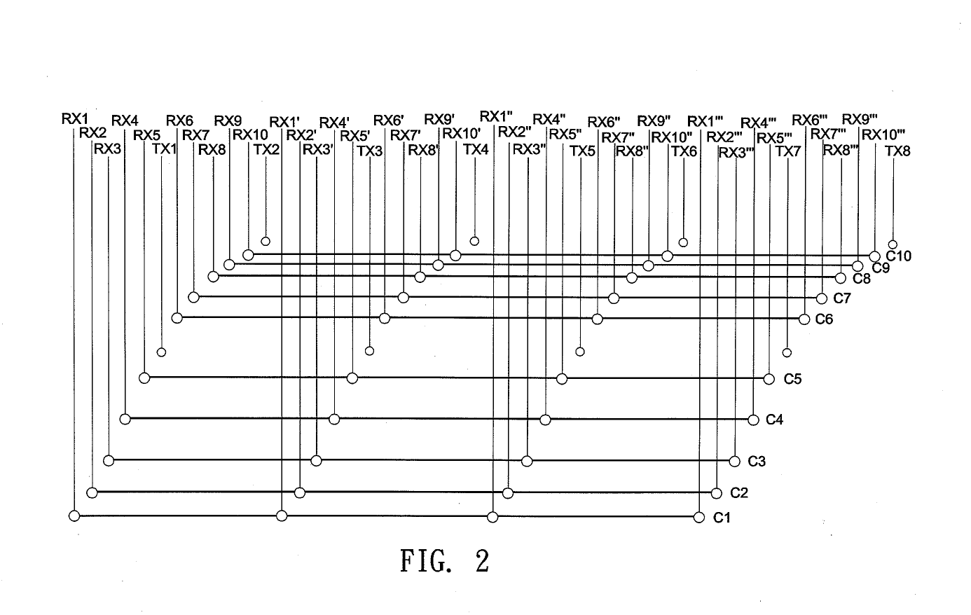

In this embodiment, a surface of the substrate 11 are divided into a plurality of regions. Each region is provided with at least one first electrode 12 and a plurality of second electrodes 14. For example, as shown in FIG. 1, the surface of the substrate 11 is divided into four regions 11a-11d. The first electrodes T1, T2 and the second electrodes R1-R10 are disposed in the region 11a, the first electrodes T3, T4 and the second electrodes R1′-R10′ are disposed in the region 11b, the first electrodes T5, T6 and the second electrodes R1″-R10″ are disposed in the region 11c, and the first electrodes T7, T8 and the second electrodes R1′″-R10′″ are disposed in the region 11d. Each first conductive line 16 is connected to one first electrode 12, each second conductive line 18 is connected to one second electrode 14, and the first conductive lines 16 do not cross the second conductive lines 18. FIG. 2 shows a schematic diagram of a wire layout of the touch-sensing structure 10 of FIG. 1 outside a touch screen area, according to an embodiment of the invention. Please refer to both FIG. 1 and FIG. 2, the first conductive lines TX1-TX8 are respectively connected to the first electrodes T1-T8, the second conductive lines RX1-RX10 are respectively connected to the second electrodes R1-R10, the second conductive lines RX1′-RX10′ are respectively connected to the second electrodes R1′-R10′, the second conductive lines RX1″-RX10″ are respectively connected to the second electrodes R1″-R10″, and the second conductive lines RX1′″-RX10′″ are respectively connected to the second electrodes R1′″-R10′″. In this embodiment, the second electrodes 14 are divided into multiple second electrode groups, and each second electrode group is formed by the second electrodes 14 collected from each of the regions 11a-11d. For example, a second electrode group may be composed of the second electrode R1 in the first region 11a, the second electrode R1′ in the second region 11b, the second electrode R1″ in the third region 11c, and the second electrode RI′″ in the fourth region 11d. Similarly, the second electrodes R2, R2′, R2″and R2′″ together form another second electrode group, and the rest may be deduced by analogy. According to this embodiment, the second conductive lines 18 connected to the second electrodes 14 in the same second electrode group are all electrically connected with each other and connected to the same bus line. For example, as shown in FIG. 1, the conductive lines RX1, RX1′, RX1″ and RX1′″ are connected with each other at a short-circuited node S. Therefore, as shown in FIG. 2, ten second electrode groups are respectively connected to ten bus lines C1-C10. Note that, since only one of the first conductive lines 16 is electrically conducted at a time, addressing each of the touch-sensing units P can be still achieved even all the second conductive lines 18 are short-circuited and electrically connected with each other. For example, when the first conductive line TX1 is enabled, the second electrodes R1, R1′, R1″ and R1′″ respectively in four regions 11a-11d are simultaneously enabled. However, a touch position is detected only when one touches a position corresponding to the second electrode RI in the region 11a spread with the first conductive line TX1, because other first conductive lines TX2-TX8 at that time are disabled and thus no change is made to the coupling capacitance even a position corresponding to the second electrodes R1′, R1″ or R1′″ is touched, therefore ensuring that only a position corresponding to the second electrode R1 in the region 11a is touched.

According to the above embodiment, when the surface of the substrate 11 is divided into four regions 11a-11d, ten second electrode groups are respectively connected to ten bus lines C1-C10, and the number of channels for the second electrodes 14 is decreased from 40 to 10. Though the number of channels for the first electrodes 12 is increased from 4 to 8, the total number of channels is considerably reduced from 44 (=4+40) to 18 (=8+10). Therefore, the problems of too many channels in a single-layer touch-sensing structure and high line impedance can be solved. Certainly, the number of regions divided from the substrate surface is not limited to the above example and may be determined according to the actual situation, such as the panel size.

Typically, the substrate 11 has a lengthwise direction L and a widthwise direction Q. In one embodiment, as shown in FIG. 1, the first electrodes 12 are arranged along the widthwise direction Q on the substrate 11; that is, each first electrode 12 has a longitudinal direction substantially parallel to the lengthwise direction L of the substrate 11. For example, when the first electrodes 12 are arranged along the widthwise direction Q and the surface of the substrate 11 is divided into four regions, the length of each first electrode 12 is allowed to be reduced to half of an original length measured without such division, therefore achieving the effect of decreasing the line load. Further, in one embodiment, the first electrodes 12 (such as electrodes T1 and T5) placed in two adjacent regions aligned along the lengthwise direction L are disposed symmetrically relative to a border line between the two adjacent regions. Moreover, in one embodiment, the second electrodes 14 in the same second electrode group are disposed symmetrically relative to a border line of two adjacent regions aligned along the lengthwise direction L. For example, the second electrode R1 and the second electrode R1″ in the same second electrode group are disposed symmetrically relative to a border line of two adjacent regions 11a and 11c, and the second electrode R1′ and the second electrode R1′″ are disposed symmetrically relative to a border line of two adjacent regions 11b and 11d that are aligned along the lengthwise direction L. In one embodiment, the second conductive lines 18 connected to the second electrodes 14 in the same second electrode group all have an equal length measured in an active display area. In case the first electrodes 12 and the second electrodes 14 have the afore-mentioned symmetric arrangement or the second conductive lines 18 connected to the same second electrode group have an equal length, the line impedance is almost equal for each region to allow to simplify the algorithm of coordinate determination. Besides, in one embodiment, the first electrodes 12 and the second electrodes 14 in each region may have an identical layout; that is, the composition and arrangement of electrodes in each region are the same.

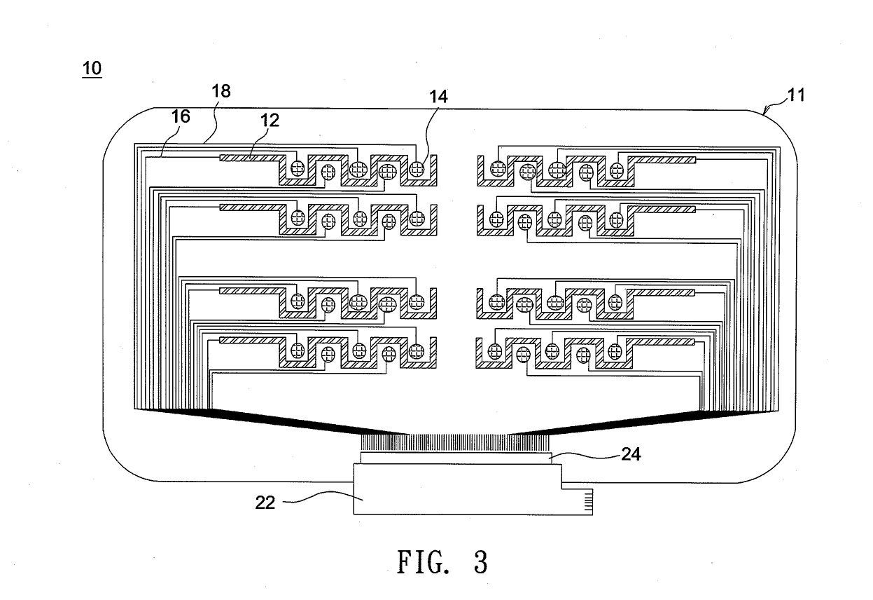

Please refer to FIG. 1 again, the afore-mentioned bus lines C1-C10 may be formed on a multi-layered flexible printed circuit board 22 to reduce the difficulty of short-circuited wiring, and then the bus lines C1-C10 are connected to a sensing terminal of an IC chip 24. In an alternate embodiment, as shown in FIG. 3, the IC chip 24 may be directly disposed on the substrate 11. In that case, the bus lines of the second conductive lines 18 are short-circuited through an internal circuit of the IC chip 24, and signals are processed by the IC chip 24 and outputted by a single-layer flexible printed circuit board 22.

Moreover, the touch-sensing structure 10 may be used in mutual-capacitive or self-capacitive sensing controls to detect touch positions. In the case of mutual-capacitive detection, the first electrodes 12 serve as driving electrodes and the second electrodes 14 as sensing electrodes, and fringe fields are induced between adjacent first electrodes 12 and second electrodes 14. When the touch-sensing unit P is touched by a finger, part of the fringe field lines are blocked or attracted by the finger to decrease the charge amount coupling to the second electrodes 14. By detecting a decrease in the coupling charge amount, a touch position can be detected. In the case of self-capacitive detection, each touch-sensing unit P has a grounded self-capacitance, the self-capacitance may vary as a result of touch events, and each touch-sensing unit P may be sensed independently.

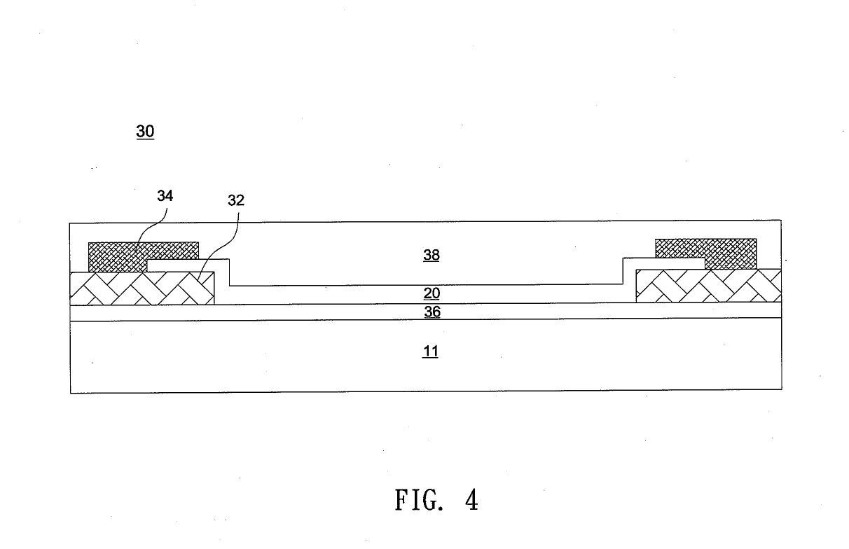

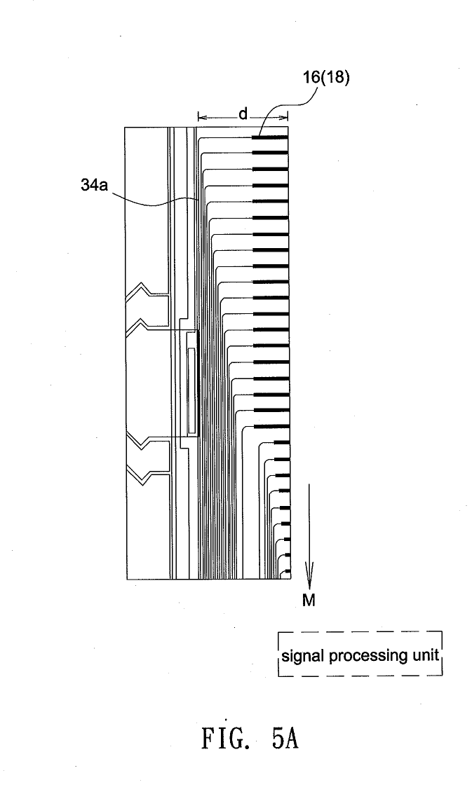

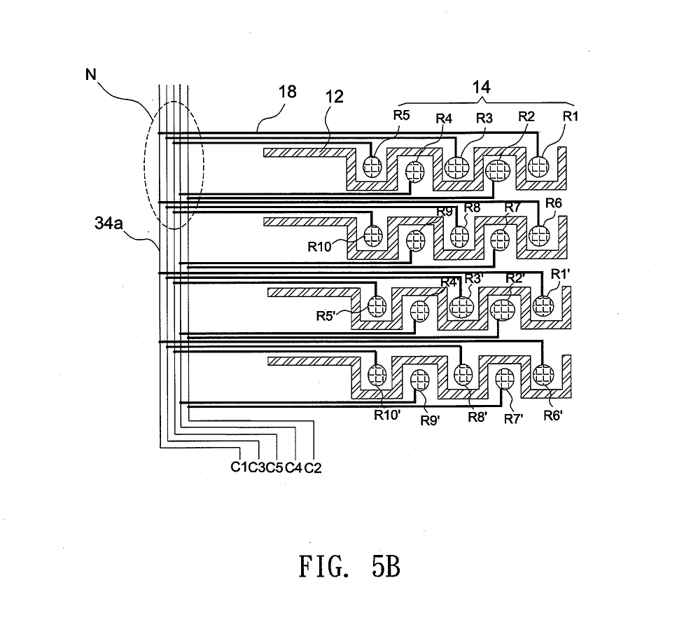

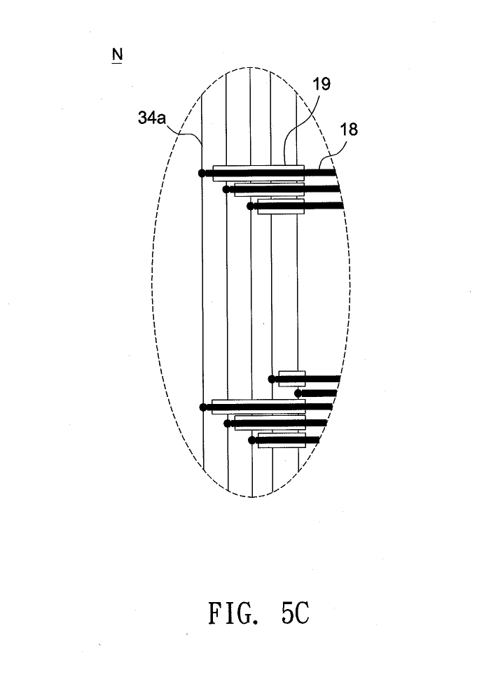

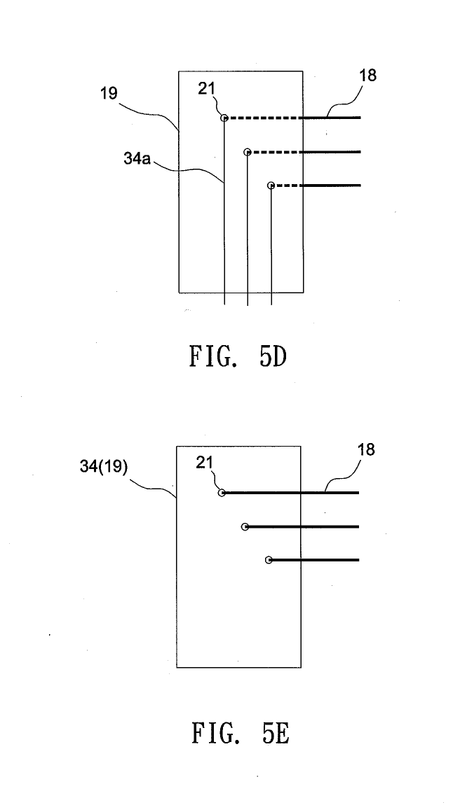

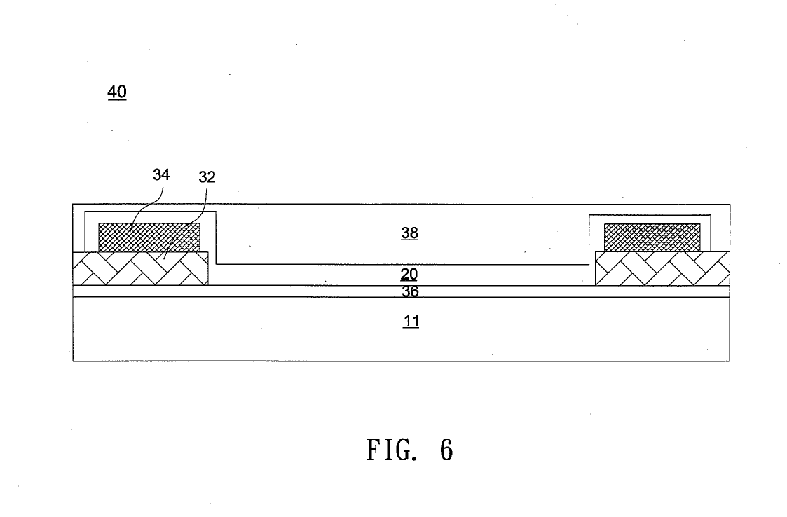

FIG. 4 shows a schematic diagram illustrating a touch-sensitive device according to another embodiment of the invention. As shown in FIG. 4, in a touch-sensitive device 30, a transparent conductive layer 20 is disposed on a substrate 11, and a decorative layer 32 is disposed on a periphery of the substrate 11. The substrate 11 may be, for example, a cover lens, and the decorative layer 32 may include at least one of ceramic, diamond-like carbon, colored ink, photo resist and resin. The transparent conductive layer 20 is patterned to form a single-layer touch-sensing structure, and a trace layer 34 is disposed on the substrate 11 and covers a part of the patterned transparent conductive layer 20. An insulation layer 36 may be optionally disposed between the transparent conductive layer 20 and the substrate 11, and a passivation layer 38 is disposed on the substrate 11 to cover the transparent conductive layer 20 and the trace layer 34. The trace layer 34 may be, for example, made of a metallic material. The trace layer 34 may be electrically connected to the flexible printed circuit board 22 shown in FIG. 3 or an IC chip 24 by, for example, an anisotropic conductive film (ACF). In this embodiment, the trace layer 34 is disposed on the substrate 11 after the transparent conductive layer 20 is patterned, and thus this prevents the etchant for patterning the transparent conductive layer 20 from etching the trace layer 34. In an alternate embodiment, as shown in FIG. 6, the trace layer 34 of the touch-sensitive device 40 is disposed on the substrate 11 first, and then the transparent conductive layer 20 is formed to entirely cover the trace layer 34 so as to prevent the etchant for patterning the transparent conductive layer 20 from etching the trace layer 34. FIG. 5A shows a schematic diagram illustrating a wire layout of FIG. 4 according to an embodiment of the invention. As shown in FIG. 5A, the trace layer 34 may be patterned to form a plurality of traces 34a. According to the an embodiment of the invention, lengths d of the first conductive lines 16 and the second conductive lines 18 measured in a non-screen area (an area overlapping the decorative layer 32) is set to gradually decrease along a direction M towards a signal processing unit (for example, an IC chip 24 or a flexible printed circuit board 22). Under the circumstance, the first conductive lines 16, the second conductive lines 18, and the traces 34a are allowed to be positioned on the same plane to eliminate the need of a bridge wiring structure. The traces 34a may be a transparent conductive layer formed together with the first conductive lines 16 and the second conductive lines 18, or the traces 34a may be an opaque conductive layer (such as a metallic conductive layer) formed separate from the conductive lines 16 and 18. In an alternate embodiment, the traces 34a may have a wiring layout shown in FIG. 5B, where the second conductive lines 18 in the same second electrode group are all connected with each other through a corresponding trace 34a to decrease the amount of the traces 34a. In that case, a width of the decorative layer 32 is allowed to be reduced to achieve a narrow-border module. Further, in case the first electrodes 12, the second electrodes 14, the first conductive lines 16 and the second conductive lines 18 are made of the same transparent conductive material (such as ITO), lengths d of the first conductive lines 16 and the second conductive lines 18 in the non-screen area may be set to gradually increase along a direction M towards a signal processing unit. Under the circumstance, the first conductive lines 16 and the second conductive lines 18 having different distances apart from the signal processing unit may have substantially the same line impedance after being connected to the traces 34a. Certainly, the disposition of the traces 34a of the trace layer 34 is not limited to the above example. Moreover, in case the first conductive lines 16 and the second conductive lines 18 are formed by patterning the transparent conductive layer 20, and the traces 34a are formed by patterning a single-layer or multi-layer metal film, a line width of each of the conductive lines 16 and the second conductive lines 18 may be set to be larger than a line width of the trace 34a. The multi-layer metal film may be, for example, a Mo/Al/Mo structure having tunable surface impedance. FIG. 5C shows a partially enlarged schematic diagram N of FIG. 5B. As shown in FIG. 5C, an insulation layer 19 is disposed between the second conductive lines 18 and the traces 34a to avoid short-circuiting. For example, when the second conductive lines 18 are to be connected to the outermost trace 34a, the second conductive lines 18 may cross over the insulation layer 19 to avoid touching other four traces 34a. Certainly, the method for insulating the traces 34a from the second conductive lines 18 is not limited to the above example. For example, as shown in FIG. 5D, the second conductive lines 18 are disposed underneath the insulation layer 19 that spreads over an entire plane. The traces 34a are disposed above the insulation layer 19 and electrically connected to the second conductive lines 18 through via holes 21. Alternatively, as shown in FIG. 5E, the insulation layer 19 spreads over an entire plane of the trace layer 34, and the second conductive lines 18 are disposed above the insulation layer 19 and electrically connected to the trace layer 34 through via holes 21.

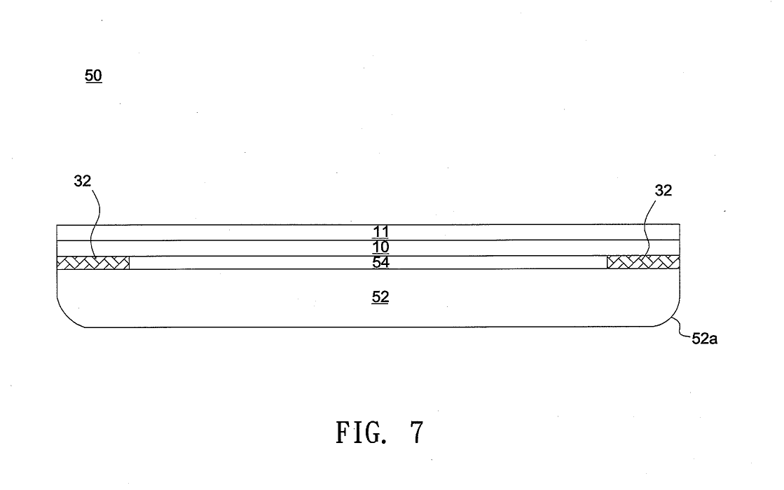

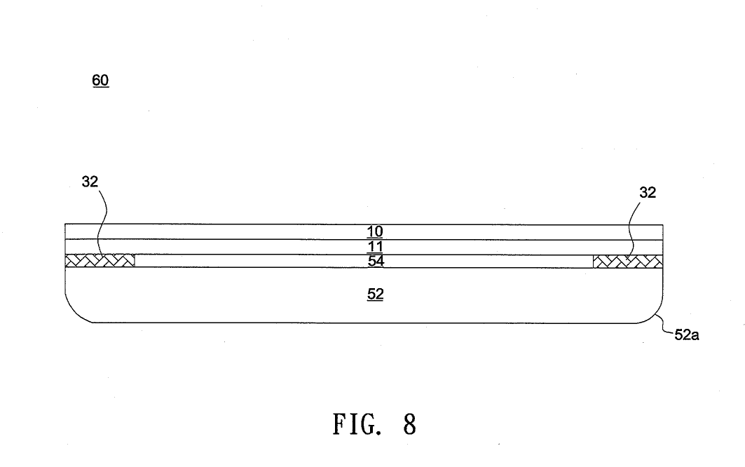

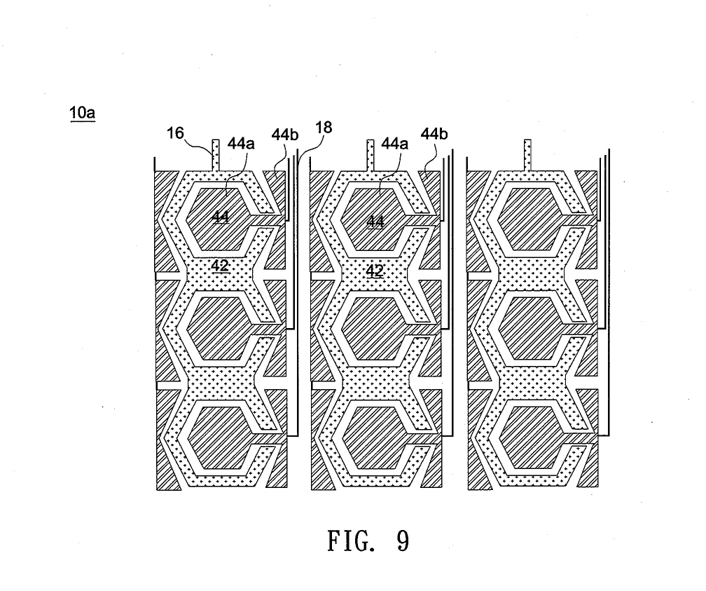

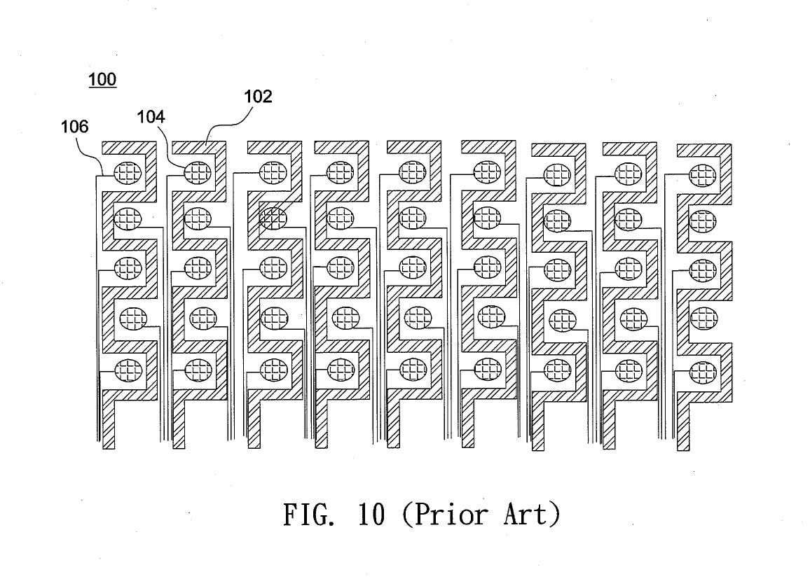

FIG. 7 shows a schematic diagram illustrating a touch-sensitive device according to another embodiment of the invention. As shown in FIG. 7, the touch-sensing structure 10 is disposed on a substrate 11 and then connected with a cover lens 52 to form a touch-sensitive device 50. The substrate 11 may be a casing or a thin film made of glass or plastic. The cover lens 52 may be connected with the touch-sensing structure 10 by, for example, an optical adhesive 54. Further, as shown in FIG. 8, the cover lens 52 may be connected with the substrate 11 having the touch-sensing structure 10 to form a touch-sensitive device 60. The cover lens 52 may have a decorative layer 32, and at least one side of the cover lens 52 may be subject to a machining treatment such as grinding and chamfering to form a curved surface 52a. In other embodiments, the substrate 11 may be one of multiple substrates of a display. For example, the substrate 11 may be a color filter substrate of the display, or an encapsulating cover of an organic light emitting diode display.

Further, the single-layer touch-sensing structure shown in FIG. 1 is merely an example, and the composition, arrangement and shape of electrodes in a single-layer touch-sensing structure are not restricted. In another embodiment shown in FIG. 9, the touch-sensing structure 10a includes first electrodes 42 and second electrodes 44. The first electrodes 42 are formed in the regions not overlapping the second electrodes 44, and each of the second electrodes 44 has a first part 44a and a second part 44b. The first electrode 42 surrounds the first part 44a of the second electrode 44. Therefore, since the first electrode 42 and the second electrode 44 are substantially surrounded with each other, the intensity of an electric field formed between the first electrode 42 and the second electrode 44 is increased to increase the amount of coupling capacitance and the sensitivity of touch-sensing controls for the touch-sensing structure 10a.

According to the above embodiments, the amount of channels needed for a single-layer touch-sensing structure is decreased, the line impedance is reduced, and the production yields are increased.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims. Each of the terms “first” and “second” is only a nomenclature used to modify its corresponding element. These terms are not used to set up the upper limit or lower limit of the number of elements.

What is claimed is:

1. A touch-sensing structure, comprising:
a substrate; and
a conductive layer spreading over a surface of the substrate, wherein the surface is divided into a plurality of regions and the conductive layer comprises:
a plurality of first electrodes spreading over the regions, wherein each region is provided with at least one of the first electrodes;
a plurality of second electrodes spreading over the regions and not overlapping the first electrodes, wherein each region is provided with several of the second electrodes, the second electrodes are divided into multiple second electrode groups, and each second electrode group is formed by at least one of the second electrodes in each of the regions;
a plurality of first conductive lines, each of the first conductive lines being connected to one of the first electrodes; and
a plurality of second conductive lines, each of the second conductive lines being connected to one of the second electrodes, wherein the second conductive lines connected to the second electrodes in the same second electrode group are electrically connected with each other.

2. The touch-sensing structure as claimed in claim 1, wherein the substrate has a lengthwise direction and a widthwise direction, and the first electrodes are arranged along the widthwise direction of the substrate.

3. The touch-sensing structure as claimed in claim 2, wherein each of the first electrodes has a longitudinal direction substantially parallel to the lengthwise direction of the substrate.

4. The touch-sensing structure as claimed in claim 2, wherein the first electrodes placed in two adjacent regions aligned along the lengthwise direction are disposed symmetrically relative to a border line between the two adjacent regions.

5. The touch-sensing structure as claimed in claim 2, wherein the second electrodes in the same second electrode group are disposed symmetrically relative to a border line between two adjacent regions aligned along the lengthwise direction.

6. The touch-sensing structure as claimed in claim 1, wherein the second conductive lines connected to the second electrodes in the same second electrode group all have an equal length measured in an active display area.

7. The touch-sensing structure as claimed in claim 1, wherein the first electrodes and the second electrodes in each region have an identical layout.

8. The touch-sensing structure as claimed in claim 1, wherein the second conductive lines connected to the second electrodes in the same second electrode group are connected to the same bus line.

9. The touch-sensing structure as claimed in claim 8, wherein each of the first electrodes and the second electrodes is made of a transparent conductive material, and the bus line is made of a metallic material.

10. The touch-sensing structure as claimed in claim 8, wherein each of the first electrodes and the second electrodes has a line width larger than a line width of the bus line.

11. The touch-sensing structure as claimed in claim 8, wherein the bus line is formed on the substrate or a flexible printed circuit board.

12. The touch-sensing structure as claimed in claim 1, wherein the first conductive lines do not cross the second conductive lines, and only one of the first conductive lines is electrically conducted at a time.

13. The touch-sensing structure as claimed in claim 1, wherein one of the second electrodes together with a part of the first electrode near the second electrode forms a mutual-capacitive or self-capacitive touch-sensing unit.

14. The touch-sensing structure as claimed in claim 1, wherein the substrate is one of multiple substrates of a display.

15. The touch-sensing structure as claimed in claim 14, wherein the substrate is a color filter substrate of the display.

16. The touch-sensing structure as claimed in claim 14, wherein the display is an organic light emitting diode display, and the substrate is an encapsulating cover of the organic light emitting diode display.

17. The touch-sensing structure as claimed in claim 1, wherein the conductive layer is in the form of a metal mesh.

18. A touch-sensitive device, comprising:
a substrate;
a conductive layer spreading over a surface of the substrate, wherein the surface is divided into a plurality of regions and the conductive layer comprises:
a plurality of first electrodes spreading over the regions, wherein each region is provided with at least one of the first electrodes;
a plurality of second electrodes spreading over the regions and not overlapping the first electrodes, wherein each region is provided with several of the second electrodes, the second electrodes are divided into multiple second electrode groups, and each second electrode group is formed by at least one of the second electrodes in each of the regions;
a plurality of first conductive lines, each of the first conductive lines being connected to one of the first electrodes; and
a plurality of second conductive lines, each of the second conductive lines being connected to one of the second electrodes, wherein the second conductive lines connected to the second electrodes in the same second electrode group are electrically connected with each other;
a trace layer disposed on the substrate and connected to the first electrodes and the second electrodes; and
a decorative layer disposed on a periphery of the substrate.

19. The touch-sensitive device as claimed in claim 18, wherein the conductive layer is a transparent conductive layer, and the trace layer is formed on at least a part of the transparent conductive layer.

20. The touch-sensitive device as claimed in claim 18, wherein the conductive layer is a transparent conductive layer, and the transparent conductive layer is formed on the trace layer and covers the trace layer.

21. The touch-sensitive device as claimed in claim 18, further comprising:
an insulation layer disposed between the conductive layer and the substrate; and
a passivation layer disposed on the substrate and covering the conductive layer and the decorative layer.

22. The touch-sensitive device as claimed in claim 18, wherein the trace layer comprises a plurality of bus lines, and the second conductive lines connected to the second electrodes in the same second electrode group are connected to the same bus line.

23. The touch-sensitive device as claimed in claim 18, further comprising:
a flexible printed circuit board having a plurality of bus lines, wherein the second conductive lines connected to the second electrodes in the same second electrode group are all connected to the same bus line.

24. The touch-sensitive device as claimed in claim 18, further comprising:
an IC chip disposed on the substrate, wherein the second conductive lines connected to the second electrodes in the same second electrode group are all connected with each other in the IC chip; and
a single-layer flexible printed circuit board electrically connected to the IC chip.

25. The touch-sensitive device as claimed in claim 18, further comprising:
an insulation layer disposed between the conductive layer and the trace layer.

26. A touch-sensitive device, comprising:
a substrate;
a conductive layer spreading over a surface of the substrate, wherein the surface is divided into a plurality of regions and the conductive layer comprises:
a plurality of first electrodes spreading over the regions, wherein each region is provided with at least one of the first electrodes;
a plurality of second electrodes spreading over the regions and not overlapping the first electrodes, wherein each region is provided with several of the second electrodes, the second electrodes are divided into multiple second electrode groups, and each second electrode group is formed by at least one of the second electrodes in each of the regions;
a plurality of first conductive lines, each of the first conductive lines being connected to one of the first electrodes; and
a plurality of second conductive lines, each of the second conductive lines being connected to one of the second electrodes, wherein the second conductive lines connected to the second electrodes in the same second electrode group are electrically connected with each other;
a trace layer disposed on the substrate, wherein the trace layer comprises a plurality of bus lines, and the second conductive lines connected to the second electrodes in the same second electrode group are connected to the same bus line; and
a cover lens connected with the conductive layer or the substrate.

27. The touch-sensitive device as claimed in claim 26, wherein the cover lens has a decorative layer.

28. The touch-sensitive device as claimed in claim 26, wherein at least one side of the cover lens is in the form of a curved surface.
